(19) United States
(12) Patent Application Publication
(10) Pub. No.: US 2024/0332135 A1
(43) Pub. Date: Oct. 3, 2024

(54) SEMICONDUCTOR PACKAGE HAVING WETTABLE FLANKS AND RELATED METHODS

(71) Applicant: SEMICONDUCTOR COMPONENTS INDUSTRIES, LLC, Scottsdale, AZ (US)

(72) Inventors: Soon Wei WANG, Seremban (MY); Jin Yoong LIONG, Seremban (MY)

(73) Assignee: SEMICONDUCTOR COMPONENTS INDUSTRIES, LLC, Scottsdale, AZ (US)

(21) Appl. No.: 18/193,847

(22) Filed: Mar. 31, 2023

(51) Int. Cl. H01L 23/495; H01L 21/56; H01L 23/00; H01L 23/31

(52) U.S. Cl. CPC H01L 23/4952; H01L 21/565; H01L 23/3157; H01L 23/4951; H01L 23/49565; H01L 24/48; H01L 2224/48247; H01L 2924/181

(57) ABSTRACT

Implementations of methods of forming semiconductor packages may include coupling a plurality of die to a pad carrier that includes a carrier and a plurality of pads, wire bonding the plurality of die to the plurality of pads, applying a mold compound over the plurality of die, removing the carrier, and singulating a plurality of semiconductor packages.

### BACKGROUND

### 1. Technical Field

Aspects of this document relate generally to methods of forming semiconductor packages. More specific implementations involve methods of forming semiconductor packages having wettable flanks.

### 2. Background

Flat no-leads semiconductor packages physically and electrically connect integrated circuits to printed circuit boards. Flat no-leads packages may include a smaller footprint as the package does not include leads or wires that extend out from the casing or molding of the semiconductor package.

### SUMMARY

Implementations of methods of forming semiconductor packages may include coupling a plurality of die to a pad carrier that includes a carrier and a plurality of pads, wire bonding the plurality of die to the plurality of pads, applying a mold compound over the plurality of die, removing the carrier, and singulating a plurality of semiconductor packages.

Implementations of methods of forming semiconductor packages may include one, all, or any of the following:

Each pad of the plurality of pads may include an etch stop layer directly coupled to the carrier, a solderable layer directly coupled to the etch stop layer, and a wire bondable layer directly coupled to the solderable layer.

The semiconductor package may include a multi-chip module package.

The plurality of pads may form a plurality of wettable flanks in each semiconductor package of the plurality of semiconductor packages.

The semiconductor package may include a chip-on-lead package.

Implementations of methods of forming semiconductor packages may include coupling a plurality of die to a pre-plated pad carrier having a metal carrier and a plurality of pre-plated pads, wire bonding the plurality of die to the plurality of pre-plated pads, applying a mold compound over the plurality of die, removing the metal carrier, and singulating a plurality of semiconductor packages. Each pre-plated pad of the plurality of pre-plated pads may include a solderable layer coupled between the metal carrier and a wire bondable layer.

Implementations of methods of forming semiconductor packages may include one, all, or any of the following:

The wire bondable layer may be directly coupled to the solderable layer.

The wire bondable layer may overhang the solderable layer and form a mold lock.

The solderable layers of the plurality of pads may be exposed on at least two sides of each semiconductor package of the plurality of semiconductor packages.

Each pre-plated pad may include an etch stop layer coupled between the solderable layer and the metal carrier.

The metal carrier may be removed through a grinding process.

The metal carrier may be removed through an etching process.

The wire bondable layer may overhang the solderable layer on at least three sides and form a mold lock.

Implementations of methods of forming semiconductor packages may include forming a pre-plated pad carrier by patterning a first layer of photoresist coupled over a metal carrier, electroplating a first metal layer over the metal carrier, patterning a second layer of photoresist coupled over the first layer of photoresist, electroplating a second metal layer over the first metal layer, and removing both the first layer of photoresist and the second layer of photoresist. The first metal layer and the second metal layer may form a plurality of pre-plated pads. The method of forming semiconductor packages may include coupling a plurality of die to the plurality of pre-plated pads, wire bonding the plurality of die to the plurality of pre-plated pads, applying a mold compound over the plurality of die, removing the metal carrier, and singulating a plurality of semiconductor packages.

Implementations of methods of forming semiconductor packages may include one, all, or any of the following:

Methods may include electroplating an etch stop layer directly to the metal carrier. The first metal layer may be electroplated over the etch stop layer.

The second metal layer of the pre-plated pad carrier may overhang the first metal layer of the pre-plated pad carrier.

The plurality of semiconductor packages may be between 0.90 mm and 0.30 mm thick.

The plurality of pre-plated pads may form wettable flanks exposed on two sides of each semiconductor package of the plurality of semiconductor packages.

The plurality of semiconductor packages may include quad-flat no-leads packages.

The second metal layer may include one of silver or NiPdAu.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a top perspective view of a semiconductor package with the mold compound removed;

FIG. 2 is a bottom perspective view of the semiconductor package of FIG. 1 with the mold compound;

FIG. 3 is a top perspective view of a pad carrier;

FIG. 4 is a magnified perspective view of a plurality of pads of the pad carrier of FIG. 3;

FIG. 5 is a top perspective view of a contact pad of the plurality of pads of FIG. 4;

FIG. 6 is a side view of the contact pad of FIG. 5;

FIG. 7 is a second implementation of a contact pad;

FIG. 8 is a side view of a carrier;

FIG. 9 is a side view of a first metal layer coupled over the carrier of FIG. 8;

FIG. 10 is a side view of a second metal layer coupled over the first metal layer of FIG. 9;

FIG. 11 is a side view of a pad carrier;

FIG. 12 is a side view of a plurality of die wire bonded to a pad carrier;

FIG. 13 is a cross-sectional side view of a mold compound formed over the plurality of die of FIG. 12;

FIG. 14 is a cross-sectional side view of the plurality of semiconductor packages being singulated;

FIG. 15 is a cross-sectional side view of a singulated semiconductor package;

FIG. 16 is a cross-sectional side view of a second implementation of a semiconductor package;

FIG. 17 is a bottom perspective view of the semiconductor package of FIG. 16;

FIG. 18 is a cross-sectional side view of a third implementation of a semiconductor package; and

FIG. 19 is a bottom perspective view of the semiconductor package of FIG. 18.

### DESCRIPTION

This disclosure, its aspects and implementations, are not limited to the specific components, assembly procedures or method elements disclosed herein. Many additional components, assembly procedures and/or method elements known in the art consistent with the intended semiconductor packages and related methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor packages, and implementing components and methods, consistent with the intended operation and methods.

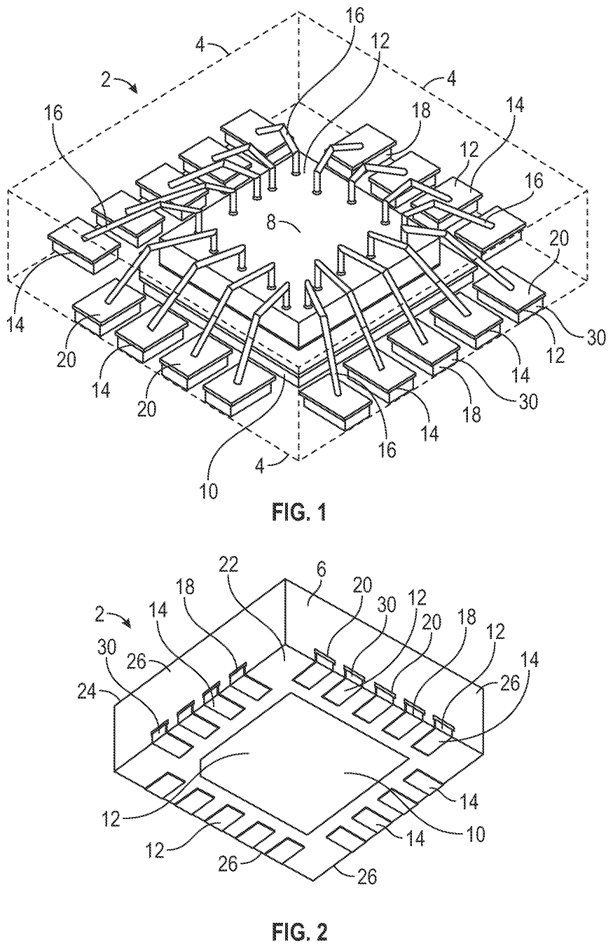

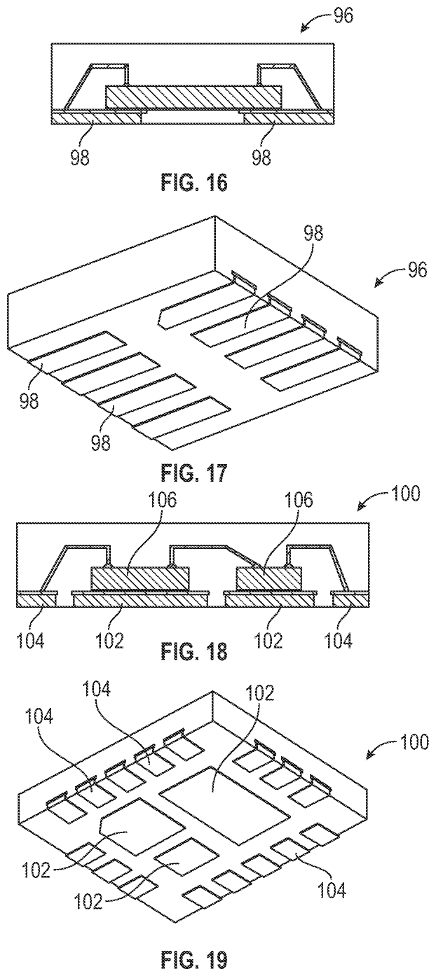

Referring to FIGS. 1-2, a first implementation of a semiconductor package (hereinafter referred to as “package”) 2 is illustrated. Referring specifically to FIG. 1, a top perspective view of a package with the mold compound removed is illustrated. The dashed lines 4 in FIG. 1 illustrate where the boundaries of the mold compound would be if a mold compound were included. Referring specifically to FIG. 2, a bottom perspective view of the package of FIG. 1 with the mold compound 6 included is illustrated. The various implementations of packages disclosed herein may be no-leads packages. As used herein, a “no-leads” package is a package with no leads extending beyond the mold compound that at least partially encapsulates the leads. In turn, a chip-on-lead (COL) package may also be considered a no-leads package if the leads are internal to the package, such as is illustrated by FIGS. 16-17. In various implementations of no-leads packages disclosed herein, the packages may include quad-flat no-leads packages (QFN), dual-flat no-leads packages (DFN), or other types of no-leads packages.

In various implementations the packages disclosed herein include a thickness of between 0.30 mm and 0.90 mm. In other implementations the package may be less than 0.30 mm thick or greater than 0.90 mm thick.

The package 2 includes a plurality of pads 12. The plurality of pads 12 may include a die attach pad 10 and a plurality of contact pads 14. In various implementations, and as illustrated by FIGS. 1-2, the package may include only a single die attach pad. In other implementations the package may include a plurality of die attach pads (such as the multi-chip module of FIGS. 18-19). The package 2 includes a die 8 coupled to the die attach pad 10. While only a single die is illustrated as coupled to the die attach pad 10 in FIG. 1, in other implementations the package may include multiple die coupled over a single die attach pad. In implementations having a plurality of die attach pads, the package may include one or more die coupled over each die attach pad of the plurality of die attach pads. The package may include a plurality of wires 16 forming a plurality of wire bonds between the die 8 and the plurality of contact pads 14. In other implementations the die 8 may be coupled to the plurality of contact pads through another coupling mechanism, such as, by non-limiting example a clip.

The package 2 includes a mold compound 6 partially encapsulating the plurality of pads 12 and encapsulating the plurality of wires 16 and the die 8.

In various implementations, each pad of the plurality of pads 12 may include a metal stack. The metal stacks may include a first metal layer 18. The first metal layer 18 may be formed from a solderable material such as tin or any other solderable material disclosed herein. In various implementations, each pad of the plurality of pads 12 may also include a second metal layer 20 directly coupled to and on the first metal layer 18. The second metal layer 20 may include a wire bondable material including any wire bondable material disclosed herein. In other implementations, each metal stack may include only a first metal layer without a second metal layer.

In various implementations, though not visible in FIGS. 1-2, the metal stack of each pad may include an etch stop layer directly coupled to each first metal layer 18 of each pad. The etch stop layer may be exposed on the second surface 22 of the package opposite the first surface 24. In other implementations, the metal stack may not include an etch stop layer. The etch stop layer may include a solderable material (including gold or a tin/gold alloy) and may also be resistant to an etchant used to remove the carrier of the pad carrier, as described herein.

The plurality of contact pads 14 may be exposed on both the second surface 22 of the package as well as the side surfaces 26 of the package. In such implementations, the contact pads 14 may form wettable flanks 30 and the solderable material of the first metal layer is exposed to provide a surface for solder fillet formation. In various implementations, a height of the wettable flanks 30 may be at least 0.100 mm. In other implementations the height of the wettable flanks 30 may be more than or less than 0.100 mm. The wettable flanks 30 are visible at the outer edge of each contact pad and may ensure a robust and proper inspection for wetting failures by automatic optical inspection.

In various implementations, the second metal layer 20 of any or all pads (including the die attach pad and the contact pads) of the plurality of pads 12 may extend beyond the perimeter of the first metal layer 18 of the corresponding pads of the plurality of pads. The second metal layer 20 may extend beyond, or overhang, one edge, two edges, three edges, or four edges of the first metal layer of the corresponding pad. In implementations having this overhang, the second metal layer 20 may form a mold lock enhancing the reliability of the mold compound encapsulating the die and the plurality of pads.

In various implementations, each of the pads may originate from a pre-plated pad carrier which may be the same as any pre-plated pad carrier disclosed herein.

Still referring to FIGS. 1-2, each of the contact pads 14 may form a full cut wettable flank. The full cut wettable flank is formed by a single right angle between the exposed bottom surface and side surface of the contact pad. In other implementations, each contact pad may include a step cut where the corner edge the exposed contact pad is removed and a step is formed between the exposed bottom and side surface of the contact pads.

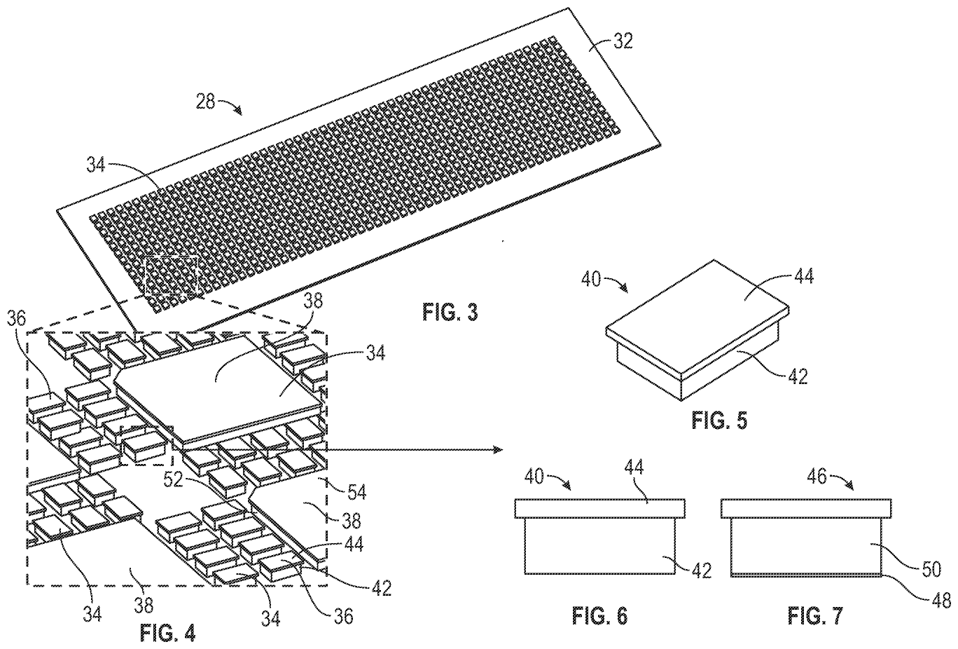

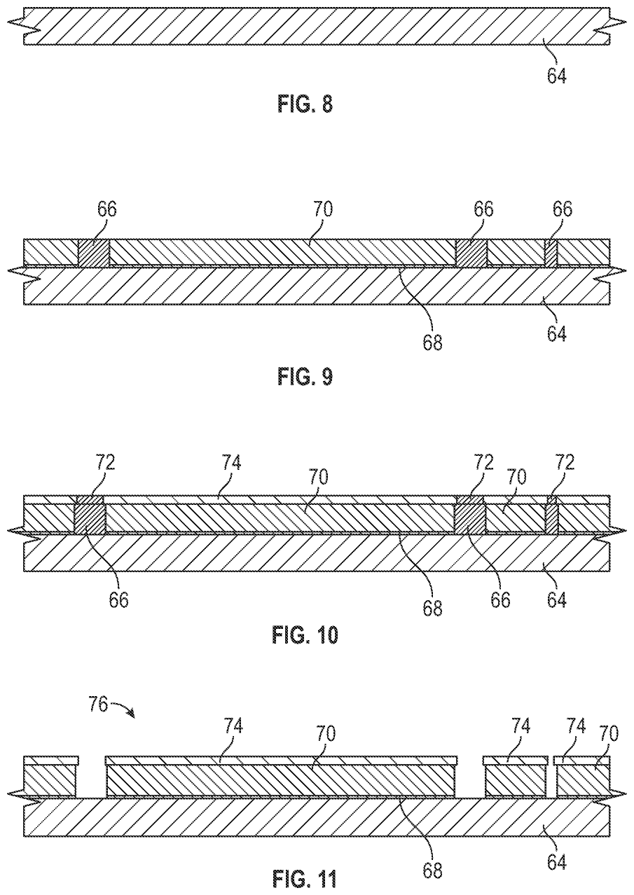

The method of forming the package of FIG. 1 includes coupling a plurality of die to a pad carrier. In various implementations, the method of forming the package may include coupling a plurality of die to a pre-existing pad carrier. In other implementations, the method of forming the package may include first forming the pad carrier and then coupling a plurality of die to the pad carrier, as illustrated by FIGS. 8-15. Referring to FIG. 3, a top perspective view of a pad carrier is illustrated. The pad carrier 28 includes a carrier 32. In various implementations, the carrier may be metal. In particular implementations, the carrier may be, by nonlimiting example, copper, a copper alloy, stainless steel, another metallic material, or any combination thereof. In other implementations, a non-metal carrier may be included in the pad carrier.

The pad carrier 28 includes a plurality of pads 34 coupled on the carrier 32. Referring to FIG. 4, a magnified perspective view of a plurality of pads 34 of the pad carrier of FIG. 3 is illustrated. The plurality of pads 34 include a plurality of contact pads 36 configured to form electrical connections external to the package. In various implementations, the plurality of pads 34 may also include a plurality of die attach pads 38. The number, shape, size, and position of contact pads and die attach pads may vary from what is illustrated the associated figures. In turn, the pad carrier may be designed for the formation of particular types of packages.

Referring to FIG. 5, a top perspective view of a contact pad of the plurality of contact pads of FIG. 4 is illustrated. Referring to FIG. 6, a side view of the contact pad of FIG. 5 is illustrated. In various implementations, and as illustrated by FIGS. 4-6, each contact pad 40 of the plurality of contact pads 36 includes a first metal layer 42 and a second metal layer 44 coupled over the first metal layer. The second metal layer 44 may be directly coupled to the first metal layer 42. The first metal layer 42 may include a solderable material. In such implementations, the first metal layer may include tin. In other implementations, the first metal layer may include other types of solderable material. The first metal layer 42 of the contact pad 40 is configured to form a wettable flank exposed on an outer surface of the finished package.

In various implementations, the second metal layer 44 coupled over the first metal layer 42 may include a wire bondable material. In particular implementations, the second metal layer 44 may include silver or NiPdAu. In other implementations, other metallic materials may be included in the second metal layer 44. As illustrated by FIGS. 4-6, the second metal layer 44 may extend beyond a perimeter of and overhang the first metal layer 42. In such of implementations, the second metal layer 44 may form a mold lock. While FIGS. 4-5 illustrate the second metal layer 44 as extending beyond all four sides of the perimeter of the first metal layer 42, in other implementations the second metal layer may extend beyond three sides of the first metal layer, two sides of the first metal layer, or a single side of the first metal layer. In still other implementations, the second metal layer 44 may not extend beyond a perimeter of the first metal layer 42.

In other implementations, the contact pad 40 may not include the second metal layer. In such implementations, the face of the first metal layer that is illustrated as directly coupled to the second metal layer may be directly coupled to a mold compound instead within the finished package.

Referring to FIG. 7, a second implementation of a contact pad 46 is illustrated. The contact pad 46 of FIG. 7 may otherwise be identical to contact pad of FIG. 6 with the only difference being that the contact pad of FIG. 7 includes an etch stop layer 48 coupled between the carrier and the first metal layer 50. The etch stop layer 48 may be directly coupled to the first metal layer 50. In particular implementations, the etch stop 48 layer may be a flash layer. The etch stop layer 48 may include gold, a tin/gold alloy, or other materials resistant to etchants that may be used in removing the carrier. Further, the etch stop layer may also include a solderable material. In turn, the combination of the etch stop layer and the first metal layer may be solderable material and may form the wettable flank exposed on the bottom surface and the side surface of the package.

While FIGS. 5-7 illustrate contact pads, it is understood that in implementations of pad carriers having a plurality of die attach pad's, such as is illustrated by FIG. 4, the die attach pads may also include a first metal layer 52, a second metal layer 54, and/or an etch stop layer similar to or the same as the corresponding layers of the contact pads illustrated by FIGS. 5-7.

In implementations where the plurality of pads all include a first metal layer and a second metal layer, the plurality of pads may be considered pre-plated and the pad carrier may be considered a pre-plated pad carrier.

Referring to FIGS. 8-11, a method of forming the pad carrier is illustrated. Referring specifically to FIG. 8, a side view of a carrier illustrated. The carrier 64 may be formed from the same material of the carrier of FIGS. 3-4. Referring to FIG. 9, a side view of a first metal layer coupled over the carrier of FIG. 8 is illustrated. In various implementations, the method may include patterning a photoresist layer 66 to correspond with the desired location and sizes of the pads of the pad carrier. In various implementations, the method may include forming an etch stop layer 68 directly on the carrier 64 and within the openings the patterned photoresist layer 66. The etch stop layer 68 may be electroplated onto the carrier 64. The etch stop layer 68 may be the same type of etch stop layer of FIG. 7. In other implementations, the method may not include the formation of the etch stop layer within the pad carrier.

Still referring to FIG. 9, the method of forming the pad carrier includes forming a first metal layer 70 over the carrier 64 within the openings of the patterned photoresist layer 66. In implementations having an etch stop layer 68, the first metal layer 70 may be directly coupled to and over the etch stop layer. In implementations not having an etch stop layer, the first metal layer 70 may be directly coupled to and over the carrier 64. The method may include electroplating the first metal layer 70 to the carrier 64 or to the etch stop layer 68. The first metal layer 70 may include any type of material of the first metal layer 42 of FIG. 4-6, including any type of solderable material. In various implementations, the first metal layer 70 and the etch stop layer 68 may have a combined minimum thickness of 0.100 mm. In other implementations the thickness of the first metal layer 70 and the etch stop layer 68 may have a combined thickness greater than or less than 0.100 mm. The thickness may be customized depending on the particular height required for the wettable flanks in the final package.

In implementations where the pad carrier is not a pre-plated pad carrier, the method of forming the pad carrier may include stripping the photoresist layer.

Referring to FIG. 10, a side view of a second metal layer coupled over the first metal layer of FIG. 9 is illustrated. In various implementations of methods of forming a pre-plated pad carrier, the method may include applying and patterning a second photoresist layer 72 over the existing photoresist layer 66. In various implementations, the second photoresist layer 72 may be patterned so the second photoresist layer is set in from the photoresist layer 66 that the second photoresist layer is formed on. In various implementations, the perimeter of the remaining portions of the second photoresist layer 72 may be smaller than the perimeter of the corresponding portions of the existing photoresist layer 66 formed under the second photoresist layer. In such implementations, the varying perimeters of the photoresist layers allow the second metal layer to form pads having mold lock features.

Still referring to FIG. 10, a method of forming a pad carrier includes forming a second metal layer 74 on the first metal layer 70 and within the patterned openings of the second photoresist layer 72. The second metal layer 74 may be electroplated onto the first metal layer 70. The second metal layer 74 may include the same materials of the second metal layer 44 of FIGS. 4-6, including any of the same wire bondable materials. In various implementations, the second metal layer 74 may include a minimum thickness of 0.020 mm. In other implementations the second metal layer may include a thickness more than or less than 0.020 mm. Referring to FIG. 11, a side view of the pad carrier is illustrated. The method of forming the pad carrier 76 may include stripping the resist layers to form the pre-plated pad carrier. The pre-plated pad carrier of FIG. 11 may be the same as the pre-plated pad carrier of FIG. 3.

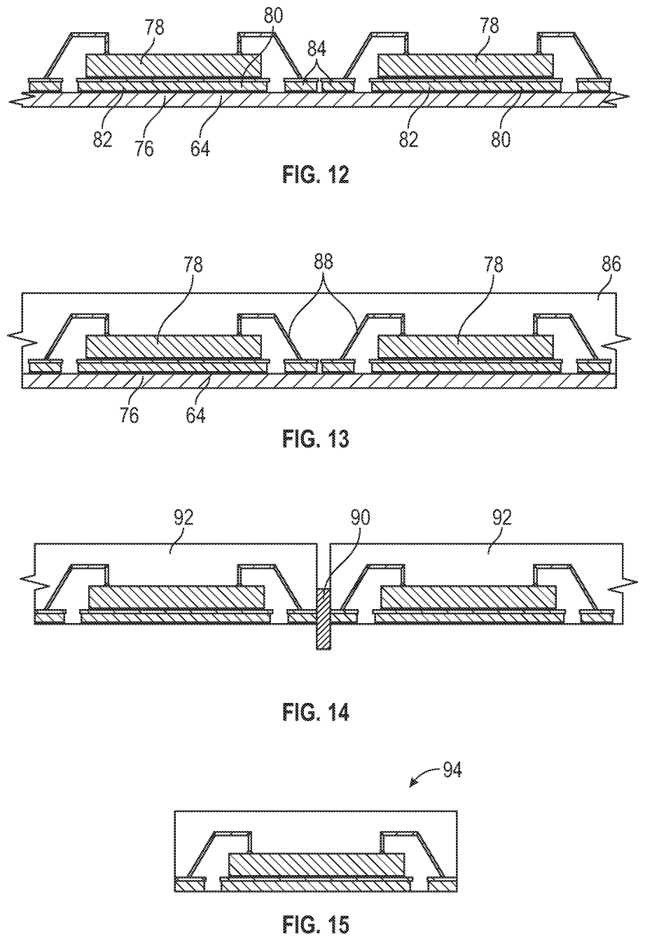

Referring to FIGS. 12-14, a method of forming the semiconductor package of FIG. 1 is illustrated. Referring specifically to FIG. 12, a side view of a plurality of die wire bonded to a pad carrier is illustrated. The method of forming the package includes coupling a plurality of die 78 over one or more pads 80 of the pad carrier 76. While FIG. 12 illustrates a single die coupled on a single pad, in other implementations multiple die may be coupled over a single pad. Further, FIG. 12 illustrates each die coupled on a die attach pad 82. In other implementations the die may be coupled on a plurality of contact pads or a combination of contact pads and a die attach pads.

In various implementations of the method of forming the package, the method may include wire bonding the plurality of die 78 to a plurality of contact pads 84. In other implementations the die may form electrical connections with the contact pads through other conductive mechanisms such as, by non-limiting example, a clip, redistribution layers, or conductive vias.

Referring to FIG. 13, a cross-sectional side view of a mold compound formed over the plurality of die of FIG. 12 is illustrated. The method of forming the package includes forming a mold compound 86 over the plurality of die 78 and between the pads 80 of the pad carrier 76. The mold compound 86 at least partially encapsulates the die 78, the wires 88, and the pads 80 of the pad carrier 76.

Referring to FIG. 14, a cross-sectional side view of the plurality of semiconductor packages being singulated is illustrated. The method of forming the package includes removing the carrier 64 of the pad carrier 76. In various implementations, the carrier 64 is removed using a grinding process. In other implementations, the carrier 64 is removed using an etching process. In methods including the etching process, the pad carrier 76 may include the etch stop layer 68 between the first metal layer 70 and the carrier 64 in order to protect the solderable material of the pads from the etchant. As illustrated by FIG. 14, the method of forming the package includes singulating a plurality of packages 92. The packages 92 may be singulated using, by non-limiting example, a saw 90, a laser, jet ablation, an etching process, any other singulation process, and any combination thereof. As illustrated in FIG. 14, singulation occurs through a portion of the plurality of contact pads 84. By removing this portion of the contact pads during singulation of the packages 92, the contact pads 84 form wettable flanks in the final package immediately upon singulation. Referring to FIG. 15, a cross-sectional side view of the singulated semiconductor package is illustrated. The singulated semiconductor package 94 of FIG. 15 may be the same as the package 2 of FIGS. 1-2. While FIG. 14 illustrates a saw 90 making a full cut to singulate the semiconductor packages, in other implementations the packages may be singulated using a step cut. In such implementations, a groove may be formed at the singulation streets and in the contact pads. the semiconductor packages may then be singulated through the singulation lines. The width of the cut used to fully singulate the packages may be less than the width of the groove, thereby forming a step cut within the wettable flakes.

In implementations of the method disclosed herein, no backside tape or film is required for the formation of the package.

Referring to FIG. 16, a cross-sectional side view of the second implementation of the semiconductor package is illustrated. Referring to FIG. 17, a bottom perspective view of the semiconductor package of FIG. 16 is illustrated. In various implementations a package 96 of FIGS. 16 and 17 is formed nearly the same way the package of FIG. 15 is formed with the difference being that the pad carrier does not include die attach pads but only includes a plurality of contact pads 98. In turn, the die may be directly coupled on two or more contact pads. In turn, the final package may include a chip-on-lead package.

Referring to FIG. 18, a cross-sectional side view of a third implementation of a semiconductor package is illustrated. Referring to FIG. 19, a bottom perspective view of the semiconductor package of FIG. 18 is illustrated. In various implementations, the package 100 of FIGS. 18 and 19 is formed nearly the same way the package of FIG. 15 is formed with the difference being that the pad carrier includes a different layout of die attach pads 102 and contact pads 104. The package also includes multiple die 106 on multiple die attach pads 102 in a single package. In turn, the semiconductor package of FIGS. 18-19 forms a multichip module.

In places where the description above refers to particular implementations of semiconductor packages and implementing components, sub-components, methods and sub-methods, it should be readily apparent that a number of modifications may be made without departing from the spirit thereof and that these implementations, implementing components, sub-components, methods and sub-methods may be applied to other semiconductor packages and related methods.

What is claimed is:

1. A method of forming a semiconductor package comprising:
coupling a plurality of die to a pad carrier, the pad carrier comprising a carrier and a plurality of pads;
wire bonding the plurality of die to the plurality of pads;
applying a mold compound over the plurality of die;
removing the carrier; and
singulating a plurality of semiconductor packages.

2. The method of claim 1, wherein each pad of the plurality of pads comprises an etch stop layer directly coupled to the carrier, a solderable layer directly coupled to the etch stop layer, and a wire bondable layer directly coupled to the solderable layer.

3. The method of claim 1, wherein the semiconductor package comprises a multi-chip module package.

4. The method of claim 1, wherein the plurality of pads form a plurality of wettable flanks in each semiconductor package of the plurality of semiconductor packages.

5. The method of claim 1, wherein the semiconductor package comprises a chip-on-lead package.

6. A method of forming a semiconductor package comprising:
coupling a plurality of die to a pre-plated pad carrier, the pre-plated pad carrier comprising a metal carrier and a plurality of pre-plated pads;
wire bonding the plurality of die to the plurality of pre-plated pads;
applying a mold compound over the plurality of die;
removing the metal carrier; and
singulating a plurality of semiconductor packages;
wherein each pre-plated pad of the plurality of pre-plated pads comprises a solderable layer coupled between the metal carrier and a wire bondable layer.

7. The method of claim 6, wherein the wire bondable layer is directly coupled to the solderable layer.

8. The method of claim 6, wherein the wire bondable layer overhangs the solderable layer and forms a mold lock.

9. The method of claim 6, wherein the solderable layer of the plurality of pads is exposed on at least two sides of each semiconductor package of the plurality of semiconductor packages.

10. The method of claim 6, wherein each pre-plated pad further comprises an etch stop layer coupled between the solderable layer and the metal carrier.

11. The method of claim 6, wherein the metal carrier is removed through a grinding process.

12. The method of claim 6, wherein the metal carrier is removed through an etching process.

13. The method of claim 6, wherein the wire bondable layer overhangs the solderable layer on at least 3 sides and forms a mold lock.

14. A method of forming a semiconductor package comprising:
forming a pre-plated pad carrier by:
patterning a first layer of photoresist coupled over a metal carrier;
electroplating a first metal layer over the metal carrier;
patterning a second layer of photoresist coupled over the first layer of photoresist;
electroplating a second metal layer over the first metal layer; and
removing both the first layer of photoresist and the second layer of photoresist, wherein the first metal layer and the second metal layer forms a plurality of pre-plated pads;
coupling a plurality of die to the plurality of pre-plated pads;
wire bonding the plurality of die to the plurality of pre-plated pads;
applying a mold compound over the plurality of die;
removing the metal carrier; and
singulating a plurality of semiconductor packages.

15. The method of claim 14, further comprising electroplating an etch stop layer directly to the metal carrier, wherein the first metal layer is electroplated over the etch stop layer.

16. The method of claim 14, wherein the second metal layer of the pre-plated pad carrier overhangs the first metal layer of the pre-plated pad carrier.

17. The method of claim 14, wherein the plurality of semiconductor packages are between 0.90 mm and 0.30 mm thick.

18. The method of claim 14, wherein the plurality of pre-plated pads form wettable flanks exposed on two sides of each semiconductor package of the plurality of semiconductor packages.

19. The method of claim 14, wherein the plurality of semiconductor packages comprise quad-flat no-leads packages.

20. The method of claim 14, wherein the second metal layer comprises one of silver or NiPdAu.
